(19) United States
(12) Patent Application Publication
(10) Pub. No.: US 2023/0043333 A1
(43) Pub. Date: Feb. 9, 2023

(54) POWER ELECTRONIC COMPONENT INTEGRATING A THERMOELECTRIC SENSOR

(71) Applicant: COMMISSARIAT A L'ENERGIE ATOMIQUE ET AUX ENERGIES ALTERNATIVES, Paris (FR)

(72) Inventors: Guillaume SAVELLI, Grenoble Cedex 09 (FR); Charlotte BRYAN, Grenoble Cedex 09 (FR); Rene ESCOFFIER, Grenoble Cedex 09 (FR); Marc PLISSONNIER, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 17/758,727

(22) PCT Filed: Jan. 14, 2021
(86) PCT No.: PCT/EP2021/050731

§ 371 Date: Jul. 13, 2022

(30) Foreign Application Priority Data
Jan. 16, 2020 (FR) FR2000404

(51) Int. Cl. G01K 7/02; G01K 7/08; H01L 23/34; H01L 29/20; H01L 29/778; H01L 35/22; H01L 35/32; H01L 35/34

(52) U.S. Cl. CPC G01K 7/028; G01K 7/08; H01L 23/34; H01L 29/2003; H01L 29/7786; H01L 35/22; H01L 35/32; H01L 35/34

(57) ABSTRACT

An electronic component may include a carrier, and a thermoelectric sensor and a power transistor which are arranged on the carrier. The power transistor may include a base layer containing a transistor material chosen from among gallium nitride, aluminium gallium nitride, gallium arsenide, indium gallium, indium gallium nitride, aluminium nitride, indium aluminium nitride, and mixtures thereof. The electronic component may be configured so that the thermoelectric sensor generates an electric current under the effect of heating from the power transistor.

The present invention relates to a power electronic component, comprising a power transistor and a thermoelectric sensor for measuring the temperature and/or the thermal flux generated by the power transistor. It also relates to a method for manufacturing a power electronic component comprising a transistor and a thermoelectric sensor.

Within a power electronic component, a power transistor, for example, based on a material such as gallium nitride (GaN), gallium arsenide (GaAs), or gallium indium (GaIn), heats up under the effect of the electrical power that it generates. It is therefore worthwhile controlling the evolution of the temperature of the transistor in order to prevent overheating of the electronic component. To this end, the thermal flux and/or the temperature of the transistor can be measured in order to adapt the electrical control of the transistor accordingly.

Currently, resistors that are variable as a function of the temperature, also called "Tsense" thermistors or resistors, are implemented in order to measure the temperature of such transistors. They are, for example:
platinum-based integrated metal thermistors that are decoupled from the active zone of the component;
thermistors based on resistive materials other than platinum, for example, made of NiCr or TaN; and
platinum-based external thermistors, or silicon-based diodes, which are disposed outside the electronic component.

These thermistors all need to be electrically powered by means of a current source. Moreover, the implementation of these resistors requires an additional step when manufacturing the integrated circuit.

Therefore, a requirement exists for simply measuring the temperature of a power transistor within an electronic component containing said power transistor, and preferably without increasing the complexity of manufacturing the electronic component.

The invention meets this requirement and proposes an electronic component comprising a carrier, a thermoelectric sensor and a power transistor disposed on the carrier, the power transistor comprising a base layer containing, preferably consisting of, a transistor material selected from among gallium nitride, aluminum gallium nitride, gallium arsenide, gallium indium, gallium indium nitride, aluminum nitride, aluminum indium nitride and mixtures thereof, the electronic component being configured so that the thermoelectric sensor generates an electric current under the effect of heating from the power transistor.

Thus, by measuring the current and/or the electric voltage on the terminals of the thermoelectric sensor, the heating and/or the temperature of the power transistor can be measured without any electric current source being required to power the thermoelectric sensor.

Preferably, the power transistor is multilayered.

Preferably, the thermoelectric sensor is multilayered and comprises a base layer.

The base layer of the thermoelectric sensor comprises, for more than 99.9% of its mass, a sensor material selected from among gallium nitride, aluminum gallium nitride, gallium arsenide, gallium indium, gallium indium nitride, aluminum nitride, aluminum indium nitride and mixtures thereof.

Preferably, the sensor material and the transistor material are identical. Advantageously, the base layers of the thermoelectric sensor and of the transistor thus can be deposited together, for example, by means of a single depositing step. Preferably, the sensor material and the transistor material are gallium nitride.

The base layer of the thermoelectric sensor and the base layer of the transistor can be deposited together using the same layer depositing method, for example, using physical vapor deposition or using chemical vapor deposition.

The base layer of the thermoelectric sensor and the base layer of the transistor can be separate. For example, they can be obtained using a method for depositing an initial layer followed by local ablation, in order to separate the initial layer into the base layer of the thermoelectric sensor and into the base layer of the transistor.

In the alternative embodiment where the sensor material and the transistor material are identical, the base layer of the thermoelectric sensor and the base layer of the transistor can be connected together and form a common layer shared by the thermoelectric sensor and by the power transistor.

The base layer of the thermoelectric sensor and the base layer of the transistor can have an identical composition.

A layer has a "lower" face facing the carrier and an "upper" face opposite the lower face.

Preferably, the base layer of the thermoelectric sensor and the base layer of the transistor have respective lower faces, disposed at the same height of the carrier. They can have identical thicknesses.

Preferably, the transistor material and the sensor material are gallium nitride and the base layer of the thermoelectric sensor can be n-doped, with the doping element being silicon in particular.

Furthermore, the power transistor can comprise a multilayered stack of transistors. The multilayered stack of transistors can comprise the following in succession:
an aluminum nitride layer that is, for example, 50 nm thick;
a layer comprising, for more than 99.9% of its mass, gallium nitride, for example, ranging between 2 µm and 4 µm thick; and
optionally, a layer comprising, for more than 99.9% of its mass, aluminum gallium nitride, for example, ranging between 10 nm and 40 nm thick.

Preferably, the thermoelectric sensor comprises a multilayered stack of sensors that has the same succession of layers as the multilayered stack of transistors.

Layers of the same row respectively within the multilayered stack of transistors and the multilayered stack of sensors preferably have the same chemical composition and can have the same thickness.

Advantageously, the thermoelectric sensor and the power transistor can be manufactured using a series of joint depositing steps in order to form the layers of the same row of the respective stacks.

For example, the multilayered stack of transistors and the multilayered stack of sensors can each comprise, in succession:
an aluminum nitride layer that is, for example, 50 nm thick;
a layer comprising, for more than 99.9% of its mass, gallium nitride, for example, ranging between 2 µm and 4 µm thick; and
optionally, a layer comprising, for more than 99.9% of its mass, aluminum gallium nitride, for example, ranging between 10 nm and 40 nm thick.

The thermoelectric sensor and the power transistor are preferably spaced apart from each other, for example, by a separation distance ranging between 1 µm and 500 µm. The thermoelectric sensor can thus easily detect an increase in the temperature of the power transistor, for example, of at least 0. 1° C.

The base layer of the thermoelectric sensor can contain at least one doping element, as a supplement at 100% of its mass. The base layer of the thermoelectric sensor thus can be n- or p-doped, as a function of the doping element. The doping results from the presence of the doping element dispersed within the base layer of the thermoelectric sensor, with the doping element modifying the electrical properties of the sensor material.

The doping element can be selected from among silicon, magnesium, carbon, zinc, oxygen, beryllium, silicon and mixtures thereof.

The doping element can be integrated within the base layer of the thermoelectric sensor during the epitaxial growth of the material or by ion implantation.

The doping element can be evenly dispersed within the base layer of the thermoelectric sensor. In other words, the concentration of doping element can be substantially constant in the base layer of the thermoelectric sensor.

As an alternative embodiment, the concentration of doping element in the base layer of the thermoelectric sensor can be variable. It can vary along the thickness of the base layer of the thermoelectric sensor. In particular, it can be higher in a portion directly under one face of the base layer of the thermoelectric sensor than in the remainder of said layer. "Directly under one face" is understood to be a portion extending by at most 100 nm, or even by at most 50 nm, or even by at most 25 nm under one face, preferably the upper face, of the base layer of the thermoelectric sensor.

The content of the doping element in a doped portion directly under one face, preferably the upper face, of the base layer of the thermoelectric sensor can be greater than 90.0%, preferably greater than 95.0%, preferably greater than 99.0%, preferably greater than 99.9%, preferably equal to 100%, as atomic percentages based on the number of atoms of the doping element contained in the base layer of the thermoelectric sensor.

In particular, the base layer of the doped thermoelectric sensor can consist of a blank portion, devoid of the doping element, and a doped portion, containing the doping element. The blank portion can form more than 90%, or even more than 95%, of the volume of the base layer of the thermoelectric sensor. The doped portion preferably extends directly under the upper face of the base layer of the thermoelectric sensor.

For example, in an alternative embodiment where the sensor material is gallium nitride, the base layer of the thermoelectric sensor can have a doped portion extending directly under its upper face over a distance of at least 10 nm and can have a blank portion extending under the doped portion over a distance ranging between 2 µm and 4 µm, with the distances being measured according to the thickness of said base layer.

Furthermore, the thickness of the base layer of the thermoelectric sensor can range between 1 µm and 5 µm, in particular between 2 µm and 4 µm.

The thermoelectric sensor comprises at least one thermoelectric couple. A thermoelectric couple comprises first and second thermoelectric members, which each have different electrical conduction properties and are electrically connected together by one of their ends.

The thermoelectric couple is configured to generate an electric voltage under the effect of a temperature change, by the Seebeck effect.

Preferably, the power transistor has at least one face facing the thermoelectric sensor that extends substantially perpendicular to the axis along which the thermoelectric couple extends.

The first thermoelectric member can be made of an n-doped or p-doped semiconductor material, and the second thermoelectric member can be made of a p-doped or n-doped semiconductor thermoelectric material, respectively, or a thermoelectric metal.

The thermoelectric metal can be selected from among titanium, gold, nickel, platinum, aluminum and alloys thereof. For example, the thermoelectric metal is aluminum.

The first thermoelectric member can be formed by all or part of a layer of the thermoelectric sensor, which is n-doped or p-doped.

According to an alternative embodiment, the base layer of the thermoelectric sensor is n-doped or p-doped and the first thermoelectric member can be formed by a portion of the base layer of the thermoelectric sensor that contains the doping element.

In particular, the first thermoelectric member can be at least partly, or even fully, formed by the doped portion of the base layer of the thermoelectric sensor, as described above, which preferably extends directly under the upper face of said base layer.

According to another alternative embodiment, the thermoelectric sensor can comprise an additional layer formed by a semiconductor material, at least one portion of which is n- or p-doped. The doped portion can extend directly under the upper face of the additional layer. Preferably, the additional layer is doped over its entire thickness.

The additional layer of the thermoelectric sensor is stacked on, and preferably is in contact with, the upper face of the base layer of the thermoelectric sensor. In particular, the doped portion of said additional layer can have an even distribution of the doping element. The first thermoelectric member can be fully or partly formed by the doped portion of said additional layer. The thickness of the additional layer of the thermoelectric sensor can range between 10 nm and 50 nm, for example, it can be equal to 25 nm.

For example, the additional layer of the thermoelectric sensor is made of aluminum gallium nitride and is doped over the entire thickness and the base layer is made of gallium nitride and is devoid of doping.

Furthermore, the width of the first thermoelectric member can range between 1.0 µm and 20.0 µm, for example, it can be equal to 4.0 µm and/or the length of the first thermoelectric member can range between 0.1 mm and 2.0 mm, for example, it is equal to 1.0 mm.

Preferably, the second thermoelectric member is stacked on the base layer of the thermoelectric sensor.

Preferably, it is at least partly housed in a groove provided in the base layer of the thermoelectric sensor and/or, if applicable, in the additional layer of the thermoelectric sensor. Preferably, the groove extends longitudinally and opens into two edges of the base layer and/or of the additional layer of the thermoelectric sensor that are opposite each other. It can extend in a curvilinear or, preferably, rectilinear direction.

The base layer of the thermoelectric sensor can comprise a doped portion and a blank portion as described above, and the groove fully passes through the doped portion, with the bottom of the groove preferably being formed in the blank portion. Preferably, the depth of the groove is greater than the thickness of the doped portion of the base layer of the thermoelectric sensor.

As an alternative embodiment, the thermoelectric sensor can comprise an additional doped layer, in contact with the non-doped base layer, and the groove fully passes through the doped portion of the additional layer, with the bottom of the groove preferably being formed in said non-doped base layer.

Thus, as will become clearly apparent hereafter, the groove can separate the doped portion of the additional layer of the thermoelectric sensor, or the doped portion of the base layer of the thermoelectric sensor, into two distinct parts. These two distinct parts thus each define two first thermoelectric members electrically insulated from each other, which can be intended to form different thermoelectric couples.

Furthermore, the groove can have a U-shaped or semi-circular section. The depth of the groove, measured between the face the groove opens into and the bottom of the groove, can range between 100 nm and 150 nm. For example, it is equal to 125 µm. The width of the groove can range between 1,500 and 3,000 nm and/or the length of the groove can range between 0.5 mm and 2.0 mm, for example, it is equal to 1.0 mm.

The second thermoelectric member can extend over the entire length and, preferably, over the entire width of the groove.

Preferably, it is in the form of a strip, which preferably is rectilinear and the width of which ranges between 1.0 µm and 3.0 µm, for example, it is equal to 2.0 µm and the length of which ranges between 0.5 mm and 2.0 mm, for example, it is equal to 1.0 mm. Furthermore, the thickness of the second thermoelectric member can range between 0.5 µm and 1.5 µm, for example, it can be equal to 1.0 µm.

Furthermore, the thickness of the second thermoelectric member can be greater than the depth of the groove. It can project from the face of the layer the groove opens into.

Preferably, when viewed in a direction normal to the carrier, the first thermoelectric member and the second thermoelectric member each assume the form of a curvilinear or preferably rectilinear strip. In particular, the ratio of the length of the first thermoelectric member, respectively of the second thermoelectric member, to the width of the first thermoelectric member, respectively of the second thermoelectric member, can be greater than 100, preferably greater than 200, preferably greater than 500.

The first and second thermoelectric members are preferably disposed parallel to each other, with a long edge of the first thermoelectric member facing a long edge of the second thermoelectric member. Thus, the thermoelectric couple extends in a longitudinal direction parallel to the longitudinal directions of the first and second thermoelectric members.

Preferably, the first and second thermoelectric members are electrically connected together in at least one electrical connection zone and are electrically insulated from each other in at least one electrical insulation zone.

Preferably, the thermoelectric sensor comprises an electrical insulation coating, disposed between the first thermoelectric member and the second thermoelectric member.

The electrical insulation coating can be in contact with the first thermoelectric member and the second thermoelectric member.

The electrical insulation coating is made of an electrically insulating material, which can be selected from the group formed by AI₂O₃, TiO₂, HfO₂, SiN, SiO₂ and mixtures thereof. Preferably, the electrically insulating material is alumina.

The length of the electrical insulation zone, measured in the extension direction of the second thermoelectric member, can range between 0.5 mm and 2.0 mm.

The electrical insulation coating can at least partially, or even fully, cover the one or more faces of the groove.

The electrical insulation zone and the electrical connection zone can be separate. The electrical insulation zone can be defined by the one or more common faces of the first and second thermoelectric members and the electrical connection zones can be defined by other faces of the first and second thermoelectric members. For example, the electrical insulation zone is defined by the one or more faces of the groove, and the respective electrical connection zones can be respectively defined by the upper faces of the first and second thermoelectric members.

As an alternative embodiment, the electrical insulation zone and the electrical connection zone can be connected. In particular, the electrical insulation zone can comprise a portion of the faces common to the first and second thermoelectric members and at least one electrical connection zone can comprise another portion of said common faces.

Preferably, the electrical connection zone is disposed less than 50 µm, or even less than 10 µm, from a longitudinal edge of the second thermoelectric member.

The ratio of the extension length of the electrical connection zone to the extension length of the electrical insulation zone can range between 0.0001 and 0.01, with said lengths being measured in the longitudinal direction of the second thermoelectric member.

The electrical connection zone can extend over a length ranging between 0.5 µm and 2.5 µm.

Furthermore, in order to provide the electrical connection between the first thermoelectric member and the second thermoelectric member, the thermoelectric sensor can be formed in various ways.

The first and second thermoelectric members can be in contact in the electrical connection zone. Preferably, the contact area between the first and second thermoelectric members is defined by part of a face common to the first and second thermoelectric members.

As an alternative embodiment, the first and second thermoelectric members can be spaced apart from each other and can be electrically connected by an electrical connector.

In particular, the electrical connector can be an electrically conductive bridge formed by one or more electrically conductive layers, in particular metal, at least partially stacked on the first thermoelectric member and the second thermoelectric member. Preferably, the material forming the electrically conductive bridge is selected from among titanium, gold, aluminum, nickel and alloys thereof, preferably it is aluminum.

The thermoelectric sensor can further comprise an electrically insulating spacer, for example, made of silicon oxide, sandwiched between the electrically conductive bridge and the first and second thermoelectric members.

The electrically conductive bridge can connect faces, for example, upper faces, of the first and second thermoelectric members, that are opposite the faces that are preferably fully covered by the electrical insulation coating.

Preferably, in order to increase the electric current or the electric voltage generated when heating the power transistor, the thermoelectric sensor comprises a plurality of thermoelectric couples.

The thermoelectric couples can be electrically connected together in parallel or, preferably, in series.

The first thermoelectric member of one of the thermoelectric couples can be electrically connected, in an electrical interconnection zone, with the second thermoelectric member of one of the other thermoelectric couples.

Preferably, the electrical interconnection zone between two thermoelectric couples is disposed at a distance from each of the electrical connection zones of the two respective thermoelectric couples. In particular, the distance between the electrical interconnection zone and the electrical connection zone of at least one, preferably of the two thermoelectric couples, is greater than 100 µm, preferably greater than 200 µm, preferably greater than 500 µm. Preferably, the first thermoelectric member of one of the thermoelectric couples is electrically connected, by means of an interconnection member, with the second thermoelectric member of one of the other thermoelectric couples. The interconnection member is preferably metal and connects the first and second thermoelectric members. Preferably, it has parts in contact with the upper faces of the first and second thermoelectric members and at least one part spaced apart from the first and second members. Another spacer made of electrically insulating material can be sandwiched between the other part of the interconnection member and the first and second thermoelectric members.

In the electrical interconnection zone, the first thermoelectric member of one of the thermoelectric couples can be in contact with the second thermoelectric member of the other thermoelectric couple. As an alternative embodiment, the first thermoelectric member of one of the thermoelectric couples and the second thermoelectric member of the other one of the thermoelectric couples can be electrically connected by an interconnection member, for example, as described above.

Furthermore, all or part of the first thermoelectric member of one of the thermoelectric couples can be spaced part from the second thermoelectric member of one of the other thermoelectric couples. In particular, said first thermoelectric member can be separated from the second thermoelectric member of the other thermoelectric couple by the electrical insulation coating of the other thermoelectric couple.

Preferably, the thermoelectric couples are aligned next to each other in an alignment direction that is oblique, preferably perpendicular, to the longitudinal direction of each thermoelectric couple.

The thermoelectric couples can be identical to each other. As an alternative embodiment, they can differ from each other. For example, they can have different dimensions and/or comprise different means for electrically connecting the first and second thermoelectric members.

In particular, the thermoelectric sensor comprises the regular, preferably periodic, repetition, in an alignment direction, of an elementary pattern formed by at least one thermoelectric couple, in particular by two electrically interconnected thermoelectric couples.

In one embodiment, the thermoelectric couples are electrically connected in series. The first thermoelectric member of one of the thermoelectric couples can be spaced apart from the first thermoelectric member of each of the other thermoelectric couples and the second thermoelectric member of one of the thermoelectric couples can be spaced apart from the second thermoelectric member of each of the other thermoelectric couples. Thus, any short circuiting within the group of thermoelectric couples is prevented. Preferably, the first thermoelectric member of one of the thermoelectric couples is electrically connected to the first thermoelectric member of at least one of the adjacent thermoelectric couples, by means of the respective second thermoelectric member of the adjacent thermoelectric couple.

Furthermore, the power transistor can be a field-effect transistor, denoted "FET" transistor. Preferably, it is of the HEMT (High Electron Mobility Transistor) type.

Preferably, the base layer of the transistor comprises the transistor material for more than 99.9% of its mass.

Furthermore, the carrier can be formed by silicon.

It can be in the form of a plate that can be more than 0.5 mm thick, for example, 1 mm thick.

The carrier can be self-supporting, i.e., it can deform, and in particular bend, without breaking under the effect of its own weight.

Furthermore, the invention relates to a device selected from among an energy converter, a control unit of a motor, a microwave power amplifier, with the device comprising an electronic component according to the invention.

The invention also relates to a method for manufacturing an electronic component comprising a power transistor and a thermoelectric sensor having first and second thermoelectric members, the method comprising the following successive steps of :
a) depositing a first material onto a substrate in order to form a base layer of the power transistor and a base layer of the thermoelectric sensor, the first material being selected from among gallium nitride, aluminum gallium nitride, gallium arsenide, gallium indium, gallium indium nitride, aluminum nitride, aluminum indium nitride and mixtures thereof;
b) n-type or p-type doping of at least one portion of the base layer of the thermoelectric sensor, or
   depositing a second material in contact with the base layer of the thermoelectric sensor in order to form an additional layer of the thermoelectric sensor, followed by n-type or p-type doping of at least one portion, preferably the whole, of the additional layer of the thermoelectric sensor,
   the second material being different from the first material and being selected from among gallium nitride, aluminum gallium nitride, gallium arsenide, gallium indium, gallium indium nitride, aluminum nitride, aluminum indium nitride and mixtures thereof;
c) forming at least one groove fully passing through the doped portion of the base layer of the thermoelectric sensor or passing through the doped portion of the additional layer of the thermoelectric sensor,
   with the doped portion of the base layer of the thermoelectric sensor or the additional layer of the thermoelectric sensor contiguous with the groove and extending along the groove defining the first thermoelectric member;
d) forming at least one electrical insulation coating covering all or part of the one or more faces of the groove;
e) forming at least one insertion layer at least partly in contact with the electrical insulation coating, and optionally p-type or n-type doping, respectively, the insertion layer, in order to form the second thermoelectric member.

The method according to the invention allows manufacturing, on the same carrier and by depositing at least the same first material, of both the power transistor and the thermoelectric sensor. It is therefore easy to implement.

Preferably, the manufacturing method is implemented in order to manufacture the electronic component according to the invention.

In step a), the substrate can comprise, or can be formed by, a carrier. The carrier can be self-supporting. For example, the carrier is a silicon plate, with a thickness of approximately 1 mm.

The substrate can further comprise a primary layer or a stack of primary layers of the thermoelectric sensor and/or a primary layer or a stack of primary layers of the power transistor, which are disposed on the substrate.

The first material can be deposited using a technique selected from physical vapor deposition and chemical vapor deposition.

Preferably, the first material comprises gallium nitride, preferably for more than 99.9% of its mass. It can be made up of gallium nitride.

The base layer of the thermoelectric sensor and the base layer of the power transistor can be contiguous and form a monolithic assembly. As an alternative embodiment, the method can comprise depositing the first material in order to form a primary layer, then ablating part of the primary layer in order to separate the primary layer into two distinct parts, respectively defining the base layer of the thermoelectric sensor and the base layer of the transistor.

The ablation of the pre-layer can be performed using lithography and etching.

"Lithography and etching" a layer is understood to mean a technique that comprises, in succession:
a step of depositing a mask, using lithography, in particular using photolithography, onto the face of the layer, the mask having at least one solid portion and at least one recessed portion; and
a step of physical or chemical etching of the part of the layer covered by the recessed portion of the mask.

The thickness of the base layer of the thermoelectric sensor and/or the thickness of the base layer of the transistor are preferably equal, for example, ranging between 2 µm and 4 µm.

Preferably, at the end of step a), the base layer of the thermoelectric sensor and the base layer of the transistor have respective lower faces, disposed at the same height of the carrier. They can have identical thicknesses.

In a first embodiment, step b) comprises n-type or p-type doping of at least one portion of the base layer of the thermoelectric sensor and step c) comprises forming at least one groove fully passing through the doped portion of the base layer of the thermoelectric sensor, with the doped portion of the base layer of the thermoelectric sensor that extends along the groove defining the first thermoelectric member.

The doping can be implemented by ion implantation of the doping element or by intrinsic doping or by in-situ doping, and preferably so that, at the end of step b), only the portion extending directly under the upper face of the base layer of the thermoelectric sensor is doped.

The doping element is selected so that, at the end of step b), the base layer of the thermoelectric sensor is n-type doped or p-type doped.

The doping element can be selected from among magnesium, carbon, zinc, oxygen, beryllium, silicon and mixtures thereof.

Preferably, the method comprises the following successive steps of:
a) depositing the first material onto the substrate in order to form the base layer of the power transistor and the base layer of the thermoelectric sensor, with the first material comprising gallium nitride for more than 99.9% of its mass; and
b) doping the portion directly under the upper face of the base layer of the thermoelectric sensor.

Furthermore, the method can comprise doping the base layer of the transistor together with doping of the base layer of the thermoelectric sensor.

In a second embodiment, step b) comprises depositing a second material in contact with the base layer of the thermoelectric sensor in order to form the additional layer of the thermoelectric sensor, followed by n-type or p-type doping of at least one portion of the additional layer of the thermoelectric sensor, with the second material being different from the first material and being selected from among gallium nitride, aluminum gallium nitride, gallium arsenide, gallium indium, gallium indium nitride, aluminum nitride, aluminum indium nitride and mixtures thereof, and step c) comprising forming at least one groove fully passing through the doped portion of the additional layer of the thermoelectric sensor, with the doped portion of the additional layer of the thermoelectric sensor contiguous with the groove and extending along the groove defining the first thermoelectric member.

The second material can be deposited using a depositing technique as described above for step a).

Preferably, the second material comprises aluminum gallium nitride, preferably for more than 99.9% of its mass. Preferably, the second material is made up of aluminum gallium nitride.

Preferably, the thickness of the additional layer of the thermoelectric sensor ranges between 10 nm and 40 nm.

Furthermore, the base layer of the thermoelectric sensor or the additional layer of the thermoelectric sensor can be doped by ion implantation of a doping element, or by intrinsic doping or by in-situ doping. Preferably, at the end of step b), the whole of the additional layer is doped.

The doping element is selected so that, at the end of step b), the base layer of the thermoelectric sensor or the additional layer of the thermoelectric sensor is n-doped or is p-doped.

The doping element can be selected from among magnesium, carbon, zinc, oxygen, beryllium, silicon and mixtures thereof.

Preferably, the method comprises the following successive steps of:
a) depositing the first material onto the substrate in order to form the base layer of the power transistor and the base layer of the thermoelectric sensor, with the first material comprising gallium nitride for more than 99.9% of its mass; and
b) depositing the second material onto the base layer of the thermoelectric sensor in order to form the additional layer of the thermoelectric sensor, and doping the whole of the additional layer of the thermoelectric sensor, with the second material comprising aluminum gallium nitride for more than 99.9% of its mass.

Furthermore, the method can comprise, in step b), together with the formation of the additional layer of the thermoelectric sensor, depositing the second material onto the base layer of the transistor in order to form an additional layer of the transistor. Furthermore, the method can comprise doping the additional layer of the transistor, for example, by means of the same doping element as for doping the additional layer of the thermoelectric sensor. The additional layer of the thermoelectric sensor and the additional layer of the transistor can have lower faces disposed at the same height relative to the carrier.

In step c), the groove can be formed using lithography and etching the base layer of the thermoelectric sensor or, if applicable, the additional layer, with the groove being defined by the zone etched in said layer.

Preferably, the groove extends longitudinally and opens into two edges of the base layer and/or the additional layer of the thermoelectric sensor that are opposite each other.

The base layer of the thermoelectric sensor can comprise a doped portion and a blank portion as described above, and the groove fully passes through the doped portion. Preferably, the depth of the groove is greater than or equal to the thickness of the doped portion of the base layer of the thermoelectric sensor. Preferably, the bottom of the groove is preferably formed in the blank portion of the base layer of the thermoelectric sensor.

As an alternative embodiment, the portion of the additional layer of the thermoelectric sensor can be in contact with the non-doped base layer, with the groove passing through said doped portion. Preferably, the depth of the groove is greater than or equal to the thickness of the doped portion of the additional layer of the thermoelectric sensor. Preferably, the bottom of the groove is formed in said non-doped base layer.

Thus, as will become clearly apparent hereafter, the groove can separate the additional layer of the thermoelectric sensor, or the doped portion of the base layer of the thermoelectric sensor, into two distinct parts. These two distinct parts thus each define two first thermoelectric members electrically insulated from each other.

Furthermore, the groove can have a U-shaped or semi-circular section. It can extend in a curvilinear or, preferably, rectilinear direction.

The depth of the groove, measured between the face the groove opens into and the bottom of the groove, can range between 100 nm and 150 nm. For example, it is equal to 125 µm. The width of the groove can range between 1,500 and 3,000 nm and/or the length of the groove can range between 0.5 mm and 2.0 mm, for example, it is equal to 1.0 mm.

Preferably, the groove extends longitudinally and opens into two edges of the base layer and/or the additional layer of the thermoelectric sensor that are opposite each other.

Preferably, a plurality of grooves is formed in step c), with two adjacent grooves being separated by a first adjacent thermoelectric member. In particular, the grooves can be formed so as to define an array of grooves.

Preferably, when viewed in a direction normal to the carrier, the grooves are in the form of a rectilinear strip.

Preferably, the grooves extend in parallel directions. They are preferably formed at a distance from each other in an oblique direction, preferably perpendicular to their extension direction. Thus, two consecutive grooves are separated by a first thermoelectric member. Preferably, two adjacent grooves can be separated by a distance ranging between 3.0 µm and 5.0 µm, for example, equal to 4.0 µm.

In step d), the electrical insulation coating can be formed by depositing an electrically insulating material into the groove. In particular, the electrical insulation coating can be formed by implementing the following successive steps of:
i) depositing an electrically insulating material onto the base layer of the thermoelectric sensor, or, if applicable, onto the additional layer of the thermoelectric sensor, in order to form a temporary layer;
ii) forming a mask using lithography and etching of the temporary layer, with the solid portion of the mask being at least partially stacked on the groove; and
iii) stripping the lithography mask.

In step i), preferably, the electrically insulating material is deposited onto a non-doped portion of the base layer of the thermoelectric sensor, or, if applicable, onto part of the non-doped portion of the additional layer of the thermoelectric sensor.

In step ii), any etching method, for example, chemical etching, known to a person skilled in the art can be used.

The electrically insulating material can be selected from Al₂O₃, TiO₂, HfO₂, SiN, SiO₂ and mixtures thereof. It is preferably made of alumina, the chemical formula of which is Al₂O₃.

The electrically insulating material can be deposited using a technique selected from among atomic layer deposition and chemical vapor deposition. Atomic layer deposition is also known as "ALD". Chemical vapor deposition is known as "CVD".

The solid portions of the lithography mask can cover less than 10% of the first thermoelectric member adjacent to the groove.

According to an alternative embodiment, the solid portions of the mask can partially cover the groove. Thus, at the end of step d), at least one face of the groove is partially not covered by the electrical insulation coating. It thus can define an electrical contact zone between the first thermoelectric member and the second thermoelectric member formed in step e).

According to another alternative embodiment, the solid portions of the mask can fully cover the one or more faces of the groove.

Preferably, the thickness of the electrical insulation coating ranges between 10 nm and 100 nm.

Preferably, according to the alternative embodiment where a plurality of grooves is formed, the method comprises forming a plurality of electrical insulation coatings each at least partially covering the one or more faces of one of the corresponding grooves. In particular, in step ii), the mask can comprise a plurality of solid portions, each being at least partially stacked on one of the corresponding grooves.

In step e), an insertion layer is formed that is at least partly in contact with the electrical insulation coating.

The insertion layer can be formed by depositing a third material in the groove.

In particular, the third material can be deposited onto the electrical insulation coating and, if applicable, onto the one or more faces of the groove defined by the doped portion of the base layer of the thermoelectric sensor or onto the doped portion of the additional layer of the thermoelectric sensor.

In particular, the insertion layer can be formed by implementing the following successive steps of:
i') depositing a third material onto the base layer of the thermoelectric sensor, or, if applicable, onto the additional layer of the thermoelectric sensor, as well as onto the electrical insulation coating, in order to form another temporary layer;
ii') forming another mask by lithography and etching of the other temporary layer, with the solid portion of the other mask being at least partially, or even completely, stacked on the temporary insulation coating; and
iii') stripping the other lithography mask.

The third material can be a thermoelectric metal, for example, aluminum.

Preferably, the solid portion of the other mask stacked on the groove assumes, as a top view, the form of a strip, preferably a rectilinear strip.

As an alternative embodiment, the third material can be made of a semiconductor material selected from among gallium nitride, aluminum gallium nitride, gallium arsenide, gallium indium, gallium indium nitride, aluminum nitride, aluminum indium nitride and mixtures thereof. Preferably, the third material is gallium nitride or aluminum gallium nitride. The method then comprises doping the insertion layer by means of a doping element selected so that the insertion layer is n-doped or p-doped if the base layer of the thermoelectric sensor and/or the additional layer of the thermoelectric sensor are p-doped or n-doped, respectively.

Thus, the insertion layer defines a second thermoelectric member.

The second thermoelectric member can extend over the entire length and, preferably, over the entire width of the groove.

Preferably, it is in the form of a strip, preferably a rectilinear strip, the width of which ranges between 1.0 and 3.0 µm, for example, it is equal to 2.0 µm and the length of which ranges between 0.5 mm and 2.0 mm, for example, it is equal to 1.0 mm. Furthermore, the thickness of the second thermoelectric member can range between 0.5 µm and 1.5 µm, for example, it can be equal to 1.0 µm.

Furthermore, the thickness of the second thermoelectric member can be greater than the depth of the groove. It can project from the face of the layer the groove opens into.

The method can comprise forming and, optionally, doping, a plurality of insertion layers, each contained in one of the corresponding grooves.

Thus, the insertion layers define, with adjacent zones of the doped portion of the base layer of the thermoelectric sensor or of the doped portion of the additional layer of the electrical sensor, a plurality of thermoelectric couples.

In particular, in step ii'), the other mask can comprise a plurality of solid portions, each being at least partially, or even fully, stacked on one of the corresponding grooves.

Preferably, the insertion layers are formed at a distance from each other. In particular, the insertion layers can form an array, preferably a substantially homothetic array, of the array of grooves. In particular, two consecutive insertion layers can be separated by portions of the base layer of the thermoelectric sensor or, if applicable, by portions of the additional layer of the thermoelectric sensor.

Thus, at the end of step f), the thermoelectric sensor can comprise a plurality of first and second thermoelectric members, which preferably are alternately disposed next to each other.

Furthermore, according to the alternative embodiment where the electrical insulation coating formed at the end of step e) only partially covers the one or more faces of the groove, the method can comprise depositing the third material in the portion of the groove not covered by the electrical insulation coating, in contact with the doped portion of the base layer of the thermoelectric sensor, or, if applicable, in contact with the doped portion of the additional layer of the thermoelectric sensor. Thus, at the end of step f), the first and second thermoelectric members are in contact with each other over a portion of their length, and are thus electrically connected. They are also electrically insulated from each other by the electrical insulation coating in the portion where the second thermoelectric member covers the electrical insulation coating. Thus, a thermoelectric couple of the thermoelectric sensor is formed.

Furthermore, in the alternative embodiment where the electrical insulation coating formed at the end of step d) fully covers the one or more faces of the groove, the method preferably comprises a step of forming an electrical connector electrically connecting the first and second thermoelectric members. Thus, a thermoelectric couple of the thermoelectric sensor is formed.

More specifically, the method can comprise forming a spacer, made of an electrically insulating material, for example, silica, stacked on the first and second thermoelectric members followed by the formation of an electrically conductive bridge electrically connecting the first and second thermoelectric members and stacked on the spacer.

In the alternative embodiment where a plurality of first and second thermoelectric members are defined, the method can comprise forming a plurality of electrically conductive bridges connecting the corresponding first and second thermoelectric members. A plurality of thermoelectric couples are thus formed.

In particular, the electrically conductive bridge can be formed on the respective upper faces of the first and second thermoelectric members.

Furthermore, the method preferably comprises forming at least one interconnection member for electrically connecting two thermoelectric couples.

More specifically, the method can comprise forming another spacer, formed by an electrically insulating material, for example, silica, stacked on the first thermoelectric member of one of the thermoelectric couples and the second thermoelectric member of the other thermoelectric couple, followed by the formation of the interconnection member, which is stacked on the other spacer and which electrically connects the first thermoelectric member of one of the thermoelectric couples to the second thermoelectric member of the other thermoelectric couple. An electrical interconnection between the thermoelectric couples is thus formed.

As an alternative embodiment, in step d), a portion of the groove intended to form the second thermoelectric member of a thermoelectric couple can be devoid of a coating and, in step e), the insertion layer is deposited in contact with the thermoelectric member of the adjacent thermoelectric couple.

Furthermore, the method can comprise, together with the formation of the electrically insulating layer of the thermoelectric sensor, forming an electrically insulating layer of the transistor made from the same material as the electrically insulating layer of the thermoelectric sensor.

The invention can be better understood from reading the following detailed description and the examples and by means of the appended drawings, in which:

FIG. 1FIG. 1 illustrates, as a cross section view, a step of the method according to a first embodiment;

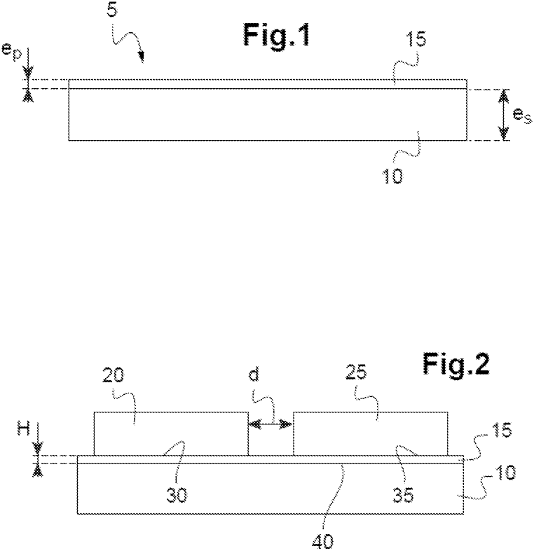

FIG. 2FIG. 2 illustrates, as a cross section view, another step of the method according to the first embodiment;

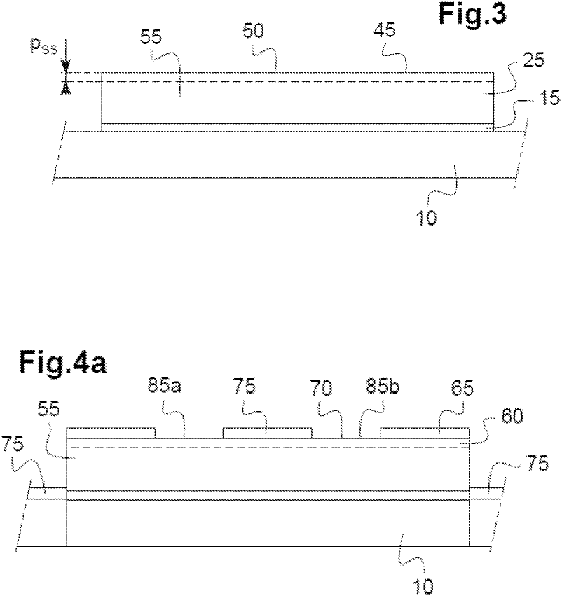

FIG. 3FIG. 3 illustrates, as a cross section view, another step of the method according to the first embodiment;

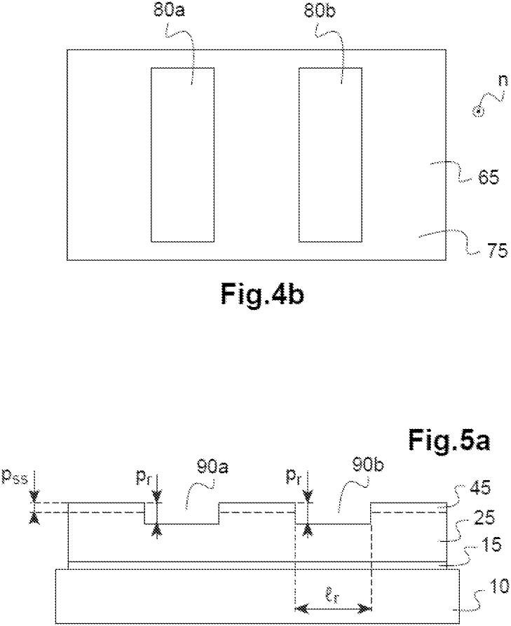

FIG. 4aFIG. 4a illustrates, as a cross section view, another step of the method according to the first embodiment;

FIG. 4bFIG. 4b illustrates, as a top view, the step of the method illustrated in FIG. 4a;

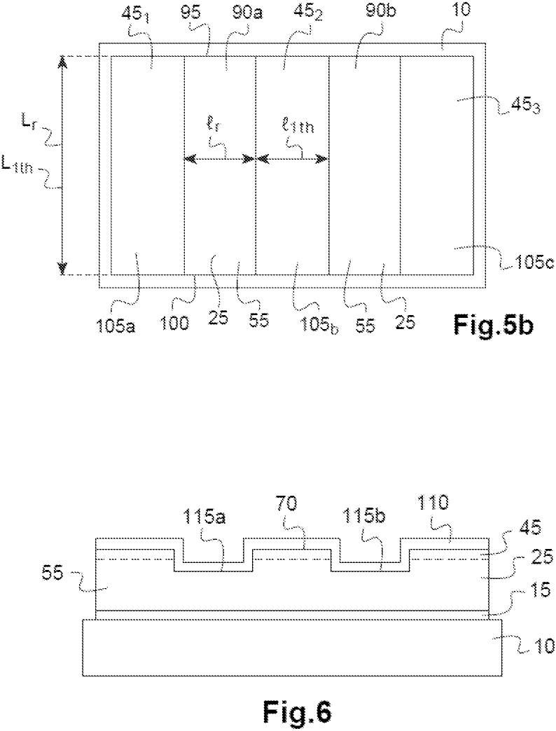

FIG. 5aFIG. 5a illustrates, as a cross section view, another step of the method according to the first embodiment;

FIG. 5bFIG. 5b illustrates, as a top view, the step of the method illustrated in FIG. 5a;

FIG. 6 FIG. 6 illustrates, as a cross section view, another step of the method according to the first embodiment;

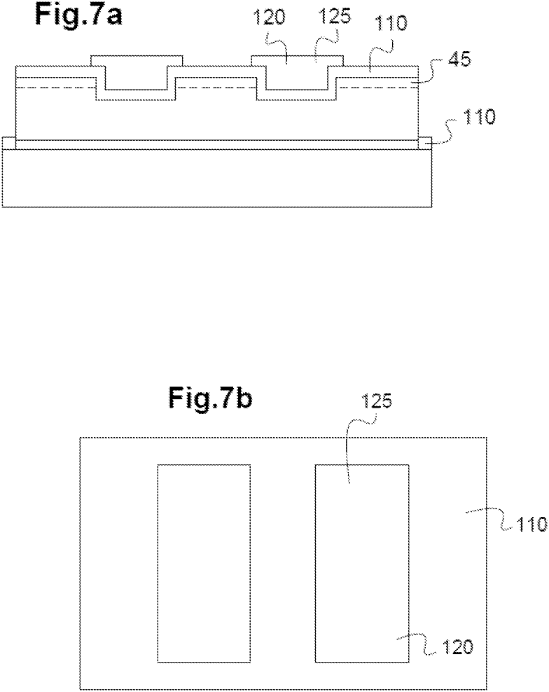

FIG. 7aFIG. 7a illustrates, as a cross section view, another step of the method according to the first embodiment;

FIG. 7bFIG. 7b illustrates, as a top view, the step of the method illustrated in FIG. 7a;

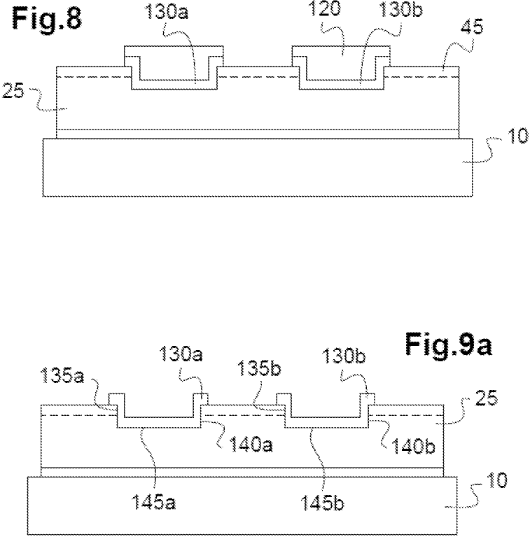

FIG. 8FIG. 8 illustrates, as a cross section view, another step of the method according to the first embodiment;

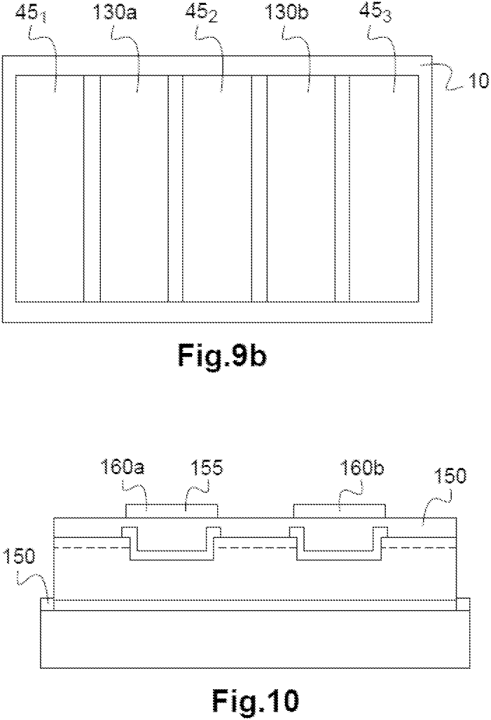

FIG. 9aFIG. 9a illustrates, as a cross section view, another step of the method according to the first embodiment;

FIG. 9bFIG. 9b illustrates, as a top view, the step of the method illustrated in FIG. 9a;

FIG. 10FIG. 10 illustrates, as a cross section view, another step of the method according to the first embodiment;

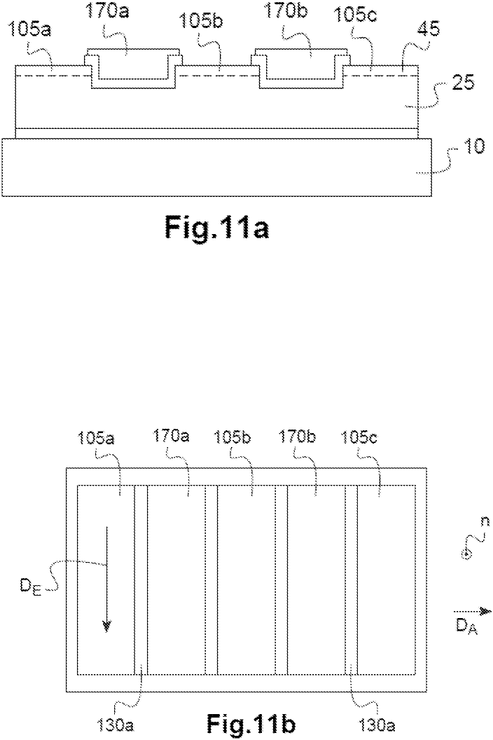

FIG. 11aFIG. 11a illustrates, as a cross section view, another step of the method according to the first embodiment;

FIG. 11bFIG. 11b illustrates, as a top view, the step of the method illustrated in FIG. 11a;

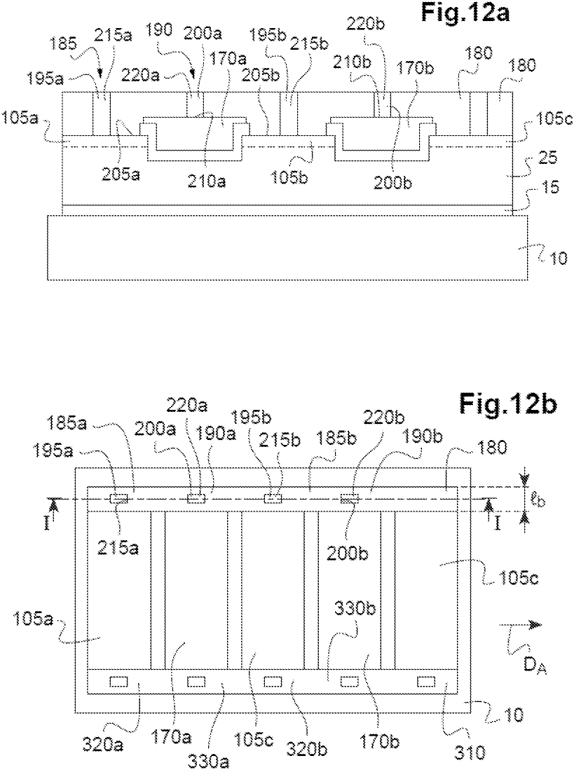

FIG. 12aFIG. 12a illustrates, as a cross section view along the cutting plane (II), another step of the method according to the first embodiment;

FIG. 12bFIG. 12b illustrates, as a top view, the step of the method illustrated in FIG. 12a;

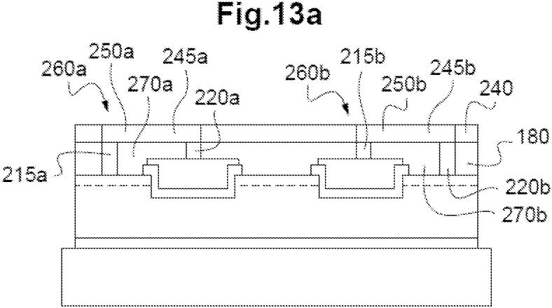

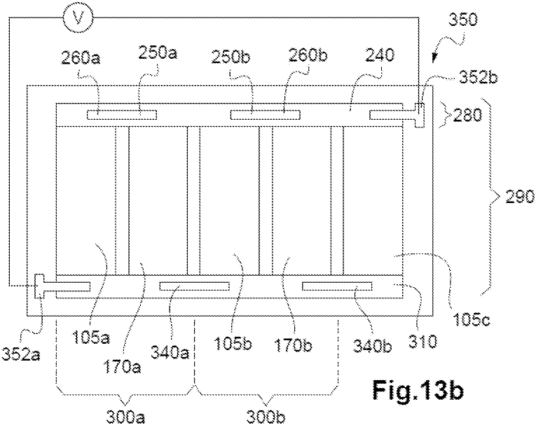

FIG. 13aFIG. 13a illustrates, as a cross section view, another step of the method according to the first embodiment;

FIG. 13bFIG. 13b illustrates, as a top view, the step of the method illustrated in FIG. 13a;

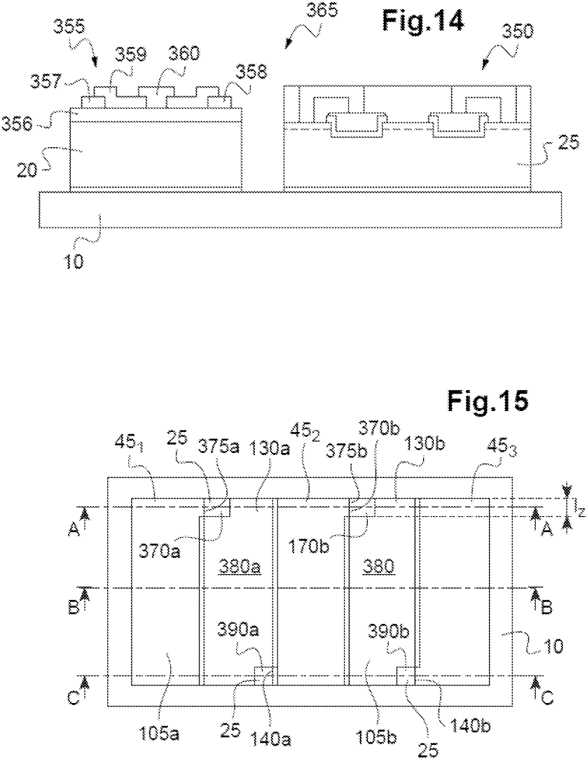

FIG. 14FIG. 14 illustrates, as a cross section view, an electronic component according to the invention manufactured according to the first embodiment;

FIG. 15FIG. 15 illustrates, as a top view, a step of the method according to a second embodiment;

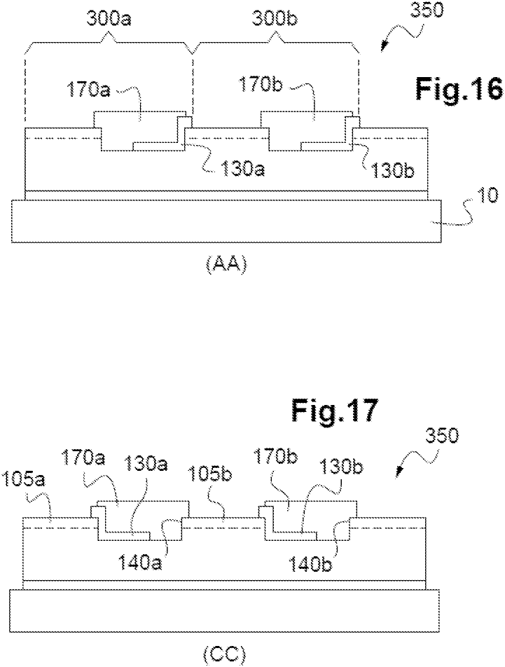

FIG. 16FIG. 16 illustrates, as a cross section view along the cutting plane (AA), the step of the method illustrated in FIG. 15;

FIG. 17FIG. 17 illustrates, as a cross section view along the cutting plane (CC), the step of the method illustrated in FIG. 15;

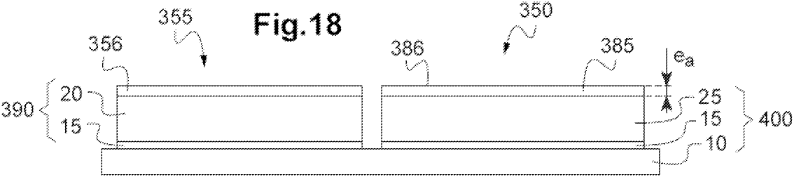

FIG. 18FIG. 18 illustrates, as a cross section view, a step of the method according to a third embodiment;

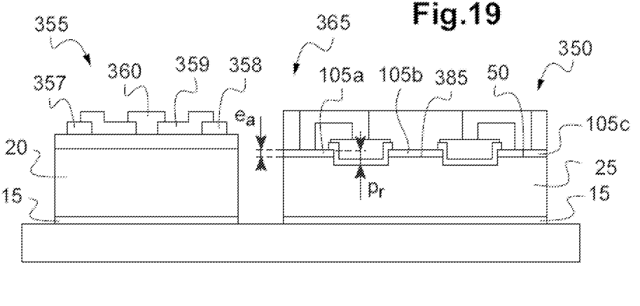

FIG. 19 illustrates, as a cross section view, an electronic component according to the invention manufactured according to the third embodiment; and

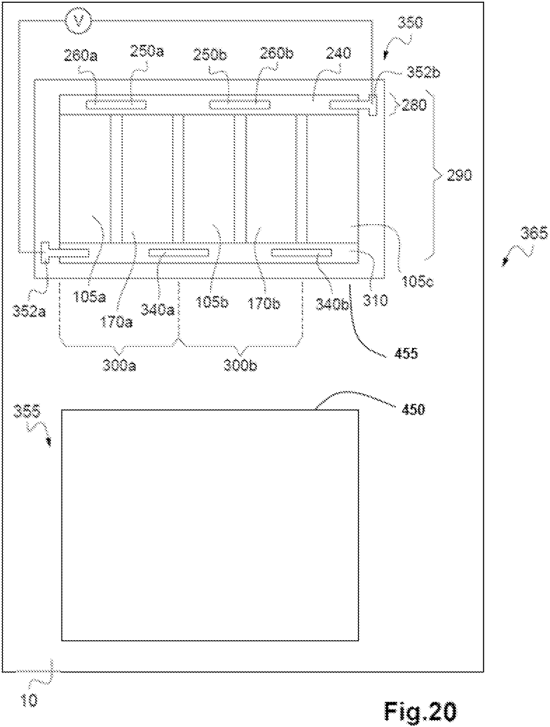

FIG. 20FIG. 20 is a schematic top view of another example of an electronic component according to the invention.

For the sake of the clarity of the drawings, the proportions of the various constituent elements of the illustrated electronic components are not shown to scale.

### Example 1

FIGS. 1 to 14 show a first embodiment of the method according to the invention for manufacturing an example of an electronic component according to the invention.

In step a), as illustrated in FIG. 1, a substrate 5 is provided that comprises a carrier 10 made of silicon and a primary layer 15 made of aluminum nitride, which covers the substrate. For example, the thickness eₛ of the carrier is equal to 1.0 mm and the thickness eₚ of the primary layer of aluminum nitride is equal to 50 nm.

In step b), gallium nitride is deposited, for example, by physical vapor deposition or by chemical vapor deposition, in contact with the primary layer of aluminum nitride. An initial layer is thus formed. The initial layer then can be separated into two separate parts, for example, using lithography and etching, in order to form a base layer 20 of the power transistor and a base layer 25 of the thermoelectric sensor, as illustrated in FIG. 2. The base layer of the power transistor and the base layer of the thermoelectric sensor are separated by a separation distance d, which is selected so that the thermoelectric sensor generates an electric voltage under the effect of heating from the transistor. The separation distance d ranges, for example, between 1 µm and 1,000 µm. Furthermore, the respective lower faces 30, 35 of the base layers 20 and 25 can be disposed at the same height H of the upper face 40 of the carrier.

According to an alternative embodiment, as illustrated in FIG. 3, the base layer 25 of the multilayer sensor is doped in step b), for example, by ion implantation. A doping element, for example, silicon, is introduced via the upper face of the base layer 25, and diffuses into a doped portion 45 directly under the upper face 50 of the base layer 25. Thus, the layer is n-doped. For example, the doped portion 45 extends over a thickness pₛₛ under the upper face that is equal to 25 nm. In FIG. 3, the dashed line represents the boundary between the blank portion 55 of the base layer 25, in which the base layer is substantially devoid of the doping element, and the doped portion 45, in which more than 99% of the doping element is concentrated.

In step c), grooves are formed on the upper face of the base layer of the thermoelectric sensor. As illustrated in FIGS. 4a and 4b, a mask 65 is formed on the upper face 70 of the base layer 25 of the thermoelectric sensor using photolithography. It comprises at least one solid portion 75, made up of, for example, a heat-sensitive resin, and recesses 80a-b stacked on portions 85a-b of the upper face of the base layer where the grooves are intended to be formed.

The base layer of the thermoelectric sensor is then etched into the portions 85a-b not covered by the solid portions of the mask. The mask is then removed by stripping. As illustrated in FIGS. 5a and 5b, grooves 90a-b are thus formed, the respective depths pᵣ of which are greater than the thickness pₛₛ of the doped portion 45. The grooves each assume the form of a strip, viewed in a direction n normal to the carrier, which extends over the entire length of the base layer of the thermoelectric sensor between two of its edges 95, 100 that are opposite one another.

Thus, first thermoelectric members 105a-c of thermoelectric couples in formation are created, which respectively comprise parts 45a, 45b and 45c of the doped portion 45.

They each assume, viewed in a direction normal to the carrier, the form of a strip, and extend parallel to the adjacent grooves.

The first thermoelectric members 105a-c are thus spaced apart and electrically insulated from each other, with the grooves having depths pᵣ that are greater than the thickness pₛₛ of the doped portion 45, and extending on either side between the edges 95 and 100.

In the illustrated example, each groove has a length Lᵣ of 1.0 mm, a width lᵣ of 2.06 µm and a depth pᵣ of approximately 125 nm, and each of the first thermoelectric members has a length L₁ₜₕ of 1.0 mm, identical to the length of a groove, a width 1₁ₜₕ of 4.0 µm and a thickness, corresponding to the thickness of the doped portion 45, that is equal to 25 nm.

In step d), an electrical insulation coating is formed. An electrically insulating material can be deposited, as illustrated in FIG. 6, onto the upper face 70 of the base layer 25 of the thermoelectric sensor, and onto the respective bottom faces 115a-b of the grooves. A temporary layer 110 is thus formed. The electrically insulating material is, for example, alumina and can be deposited using CVD, ALD or PECVD.

A mask 120 is then generated using photolithography, with the solid portions 125 of the mask being fully stacked on the groove, as illustrated in FIGS. 7a and 7b. The temporary layer is then etched in the one or more parts thereof not covered by the solid portions of the mask, as illustrated in FIG. 8. After stripping the solid portions of the mask, electrical insulation coatings 130a-b are formed, each entirely covering the side faces 135a-b, 140a-b and the bottom face 145a-b of each of the grooves. Thus, each electrical insulation coating extends along the entire width and over the entire length of the groove that it covers.

In step e), in the illustrated example, a third material, for example, a thermoelectric metal, in particular aluminum, is deposited onto the upper face of the base layer of the thermoelectric sensor and onto the electrical insulation coating, so as to form another temporary layer 150. Another mask 155 is then formed using photolithography, the solid portions 160a-b of which fully cover the groove, as illustrated in FIG. 10.

After etching the other temporary layer and stripping the other mask, insertion layers 170a-b are formed that each completely fill a corresponding groove. Each insertion layer projects from the upper face of the base layer of the thermoelectric sensor. Furthermore, with the insertion layers being formed by a thermoelectric material, they each define the second thermoelectric members 175a-b intended to form, with corresponding first thermoelectric members, thermoelectric couples.

Each second thermoelectric member is thus contiguous with a first thermoelectric member. The electrical insulation coating forms a barrier between a first thermoelectric member and a second adjacent thermoelectric member, which are thus electrically insulated from each other, as illustrated in FIGS. 11a and 11b.

Furthermore, when viewed in the direction n normal to the carrier, the first and second thermoelectric members each extend in extension directions D_{E} parallel to each other, and are alternately aligned side by side in an alignment direction D_{A} perpendicular to the extension direction D_{E}. Two adjacent first and second thermoelectric members thus form a pattern that is regularly repeated in the alignment direction D_{A}.

In an alternative embodiment, not illustrated, the third material can be a semiconductor and the method can comprise doping the insertion layer in order to impart thermoelectric properties thereto. In the illustrated example, the base layer 25 is made of n-doped gallium nitride, the third material can be gallium nitride or aluminum gallium nitride, and the insertion layer can be p-doped by implanting beryllium, magnesium, zinc or carbon.

As described above, in the illustrated example, at the end of step e), the first thermoelectric members are electrically insulated from the second thermoelectric members by means of the electrical insulation coating. In order to form thermoelectric couples capable of generating a Seebeck effect, the method implemented in example 1comprises depositing a first silica layer 180, which covers both the parts 185a-b, 190a-b of the longitudinal ends of the first thermoelectric members and the second thermoelectric members, respectively. As illustrated in FIGS. 12a and 12b, the first silica layer extends on either side of the base layer of the thermoelectric sensor and on the insertion layers, in the alignment direction D_{A}. When viewed in the direction normal to the carrier, the silica layer thus assumes the form of a rectilinear strip, the width 1_{b} of which is, for example, equal to 5.5 µm. Furthermore, the first silica layer comprises first 195a-b and second 200a-b openings passing through the thickness thereof and which open into the upper face 205a-b of the first thermoelectric member and into the upper face 210a-b of the second thermoelectric member, respectively. Furthermore, the method comprises forming first 215a-b and second 220a-b electrically conductive pads, for example, made of metal, and in particular made of aluminum, which are housed in the openings. The openings, as well as the electrically conductive pads, can be successively formed using a lithography and etching technique as described elsewhere in this description.

Finally, the method implemented in example 1 comprises, as illustrated in FIGS. 13a and 13b, forming a second silica layer 240, which is fully stacked on the first silica layer 180, and vice versa. The second layer comprises another opening 245a-b, which fully passes through the thickness thereof and which opens into the first 220a-b and second 225a-b electrically conductive pads. The other opening is also stacked on the first silica layer and on a first thermoelectric member and on a second adjacent thermoelectric member. An electrically conductive strip 250a-b, for example, made of aluminum, is housed in the opening and is in contact with the first and second electrically conductive pads. Thus, the pads and the electrically conductive strip define an electrically conductive bridge 260a-b that connects adjacent first 105a-b and second 170a-b thermoelectric members. Furthermore, the portion of the first silica layer sandwiched between the electrically conductive bridge and the thermoelectric members is an electrically insulating spacer 270a-b.

The first and second thermoelectric members are thus electrically connected in an electrical connection zone 280 extending over the longitudinal end portion over a length that is less than the width 1_{b} of the silica strip, and are electrically insulated from each other over an electrical insulation zone 290 that extends over the length of the groove. Thermoelectric couples 300a-b are thus created, which each comprise first 105a-b and second 170a-b thermoelectric members connected by the electrically conductive bridge 260a-b, respectively, which under the effect of heating from the transistor is capable of generating an electric current by the Seebeck effect.

In order to increase the voltage generated by the sensor, the thermoelectric couples can be interconnected in series with one another. In conjunction with the formation of the first silica layer 180, the method comprises forming another silica layer 310, which covers the longitudinal end parts 320a-b, 330a-b of the first thermoelectric members and the second thermoelectric members, respectively, opposite the first silica layer 180. Interconnection members 340a-b connecting the second thermoelectric member, for example, 170a, of a thermoelectric couple, for example, 300a, to the first thermoelectric member, for example, 105b, of an adjacent thermoelectric couple, for example, 105b, are formed, according to a method identical to that described above for generating the electrically conductive bridges.

A thermoelectric sensor 350, formed by thermoelectric couples electrically connected in series, is thus obtained by means of the method implemented in example 1.

It can be connected to a voltmeter or an ammeter, by means of connection pastes 352a-b deposited onto the carrier and to which it is connected, for measuring the electric voltage or the electric current respectively generated by the power transistor 355 disposed nearby on the carrier, as illustrated in FIG. 14.

Furthermore, the method can comprise forming one or more layers stacked on the base layer of the transistor in order to form the power transistor 355.

For example, the method comprises forming an additional layer 356 of the transistor, for example, formed by aluminum gallium nitride, in contact with the base layer 20 of the gallium nitride transistor. The additional layer of the transistor is, for example, n-doped in the illustrated example. It can be formed by a step following the step of depositing the base layers of the transistor and of the thermoelectric sensor. The method further comprises forming a drain layer 357 and a source layer 358, which are metal and which, for example, are partly formed during the operation of depositing the third material of the insertion layer of the thermoelectric sensor. An insulation layer 359 of the transistor and a gate layer 360 finally can be formed on the additional layer. An electronic component 365 comprising an HEMT-type power transistor 355 is thus obtained that is disposed on the carrier near the thermoelectric sensor 350.

The electronic component 365 illustrated in FIG. 20 differs from that illustrated in FIG. 14 by disposing the transistor 355 relative to the thermoelectric sensor 350. A face 450 of the transistor is disposed facing a face 455 of the thermoelectric sensor, which is substantially perpendicular to the extension directions of the first 105a-b and second 170a-b thermoelectric members. Such a relative disposition of the transistor relative to the thermoelectric sensor optimizes the generation of an electric current by the thermoelectric sensor when the transistor is heated. The accuracy of the measurement of the increase in temperature of the transistor thus can be improved.

### Example 2

The thermoelectric sensor of the electronic component of example 2, according to the invention, differs from that illustrated in example 1in that the first and second thermoelectric members of a thermoelectric couple are in direct contact with each other in an electrical connection zone 370.

The thermoelectric sensor can be manufactured by implementing steps a) to c) described above in order to form a groove in the doped base layer of the thermoelectric sensor.

As illustrated in FIG. 15, the manufacturing method differs from that implemented in example 1in that an electrical insulation coating 130a-b is formed that partially covers only the faces of the groove. In order to form such a coating, a mask is deposited onto the temporary layer 110, which is not stacked on a portion of the groove in a longitudinal end portion 370a-b of the groove. In particular, in said longitudinal end portion, the electrical insulation coating 130a covers the part of the groove contiguous with a doped portion 45₂ of the base layer of the thermoelectric sensor intended to form a first thermoelectric member 105b of another adjacent thermoelectric couple. Thus, the formation of a short circuit within the thermoelectric sensor is prevented.

The method then comprises forming an insertion layer as described in example 1, which fills the entire volume of the groove. As illustrated in FIG. 16, the second thermoelectric member 170a-b thus formed is, in the end portion of the groove, in direct contact with a first adjacent thermoelectric member in an electrical connection zone 375a-b and is electrically insulated from the other adjacent first thermoelectric member. The electrical contact zone can particularly extend, over a distance L_{z} measured along the length of the groove, by less than 10 µm. Furthermore, in the electrical insulation zone 380a-b, where the electrical insulation coating entirely covers the faces of the groove, the first and second thermoelectric members are spaced apart from each other and are electrically insulated, as illustrated in FIG. 11a.

The method according to the second example is thus particularly simple to implement. The thermoelectric sensor can be manufactured with a limited number of layers to be deposited.

Furthermore, in order to interconnect two adjacent thermoelectric couples, the electrical insulation coating is not stacked, in the opposite end portion 390a-b of the groove, on the face of the groove 140a-b contiguous with the doped portion of the base layer of the thermoelectric sensor intended to form a first thermoelectric member of another thermoelectric couple. Thus, in the electrical interconnection zone as illustrated in FIG. 17, the second thermoelectric member 170a of a thermoelectric couple 300a is in direct contact with the first thermoelectric member 105b of the adjacent thermoelectric couple 300b. The adjacent thermoelectric couples are thus connected in series.

### Example 3

The manufacturing method according to the invention implemented in example 3 differs from that implemented in example 1 in that in step b) it comprises depositing a second contact material of the base layer of the thermoelectric sensor in order to form an additional layer 385 of the thermoelectric sensor.

Preferably, the second material is simultaneously deposited, in step b), onto the base layer of the transistor in order to form an additional layer of the transistor 356. Thus, the thermoelectric sensor 350 and the power transistor can respectively comprise a multilayered stack of sensors 390 and a multilayered stack of transistors 400 arranged on the carrier 10 and formed by a succession of layers comprising the same materials.

In the example illustrated in FIGS. 18 and 19, the multilayered stack of sensors and the multilayered stack of transistors comprise the same succession of layers formed by:
a primary layer 15 made of aluminum nitride;
a base layer 20, 25 made of non-doped gallium nitride; and
an additional layer 356, 385 made of aluminum gallium nitride.

Furthermore, the method comprises doping the additional layer of the sensor, and optionally the additional layer of the transistor. In the illustrated example, at the end of step b), the additional layer of the thermoelectric sensor is made of n-doped aluminum gallium nitride over its entire thickness. As an alternative embodiment, it can be doped on only one portion, which, for example, extends directly under the upper face 386 of the additional layer of the thermoelectric sensor.

In step c), grooves are formed in accordance with a lithography and etching technique as described in example 1, with the method being conducted such that the depth pᵣ of the groove is greater than or equal to the thickness eₐ of the additional doped layer, with the bottom of each groove being defined by a face of the base layer of the thermoelectric sensor made of non-doped gallium nitride. Thus, first thermoelectric members 105a-c, formed by n-doped gallium aluminum nitride are formed, which are electrically insulated from each other by the base layer of the thermoelectric sensor.

The other steps for forming the second thermoelectric members, then for connecting between the first and second thermoelectric members in order to create thermoelectric couples, and finally for connecting the thermoelectric couples in series, are identical to those described in example 1.

As an alternative embodiment, the transistor of the electronic component of FIG. 19 can be disposed relative to the thermoelectric sensor, as illustrated in FIG. 20.

### Example 4

The manufacturing method of example 4, not illustrated, differs from that described in example 3, in that it comprises a step of forming the electrical insulation coating as described in example 2. Thus, the second thermoelectric member is in contact with the first thermoelectric member made of doped aluminum gallium nitride in the electrical connection zone.

Of course, the invention is not limited to the examples and embodiments of the electronic component and to the embodiments of the method described in the application. For example, the thermoelectric sensor can be formed on another carrier, then transferred onto the carrier on which the power transistor rests.

1. An electronic component, comprising;
a carrier;
a thermoelectric sensor; and
a power transistor,
wherein the thermoelectric sensor and the power transistor are disposed on the carrier,
wherein the power transistor comprises a base layer comprising a transistor material comprising gallium nitride, aluminum gallium nitride, gallium arsenide, gallium indium, gallium indium nitride, aluminum nitride, aluminum indium nitride, or a mixture thereof,
wherein the electronic component is configured so that the thermoelectric sensor generates an electric current under the effect of heating from the power transistor.

2. The electronic component of claim 1, wherein the thermoelectric sensor is multilayered and comprises a base layer (25) comprising, for more than 99.9% of its mass, gallium nitride, aluminum gallium nitride, gallium arsenide, gallium indium, gallium indium nitride, aluminum nitride, aluminum indium nitride, or a mixture thereof, as a sensor material .

3. The electronic component of claim 2, wherein the base layer of the thermoelectric sensor is n-doped or p-doped by a doping element.

4. The electronic component of claim 3, wherein the base layer of the thermoelectric sensor comprises a blank portion devoid of the doping element, and a doped portion comprising the doping element.

5. The electronic component of claim 1 , wherein the thermoelectric sensor comprises a thermoelectric couple comprising a first thermoelectric member and a second thermoelectric member,
wherein the first thermoelectric member comprises an n-doped or p-doped semiconductor material, and
wherein the second thermoelectric member comprises a p-doped or n-doped semiconductor thermoelectric material, respectively, or of a thermoelectric metal.

6. The electronic component of claim 5, wherein the first thermoelectric member is formed by all or part of a layer of the thermoelectric sensor, which is n-doped or p-doped.

7. The electronic component of claim 2 5, wherein the thermoelectric sensor comprises an additional layer comprising a semiconductor material,
wherein at least a portion of the semiconductor material of the additional layer is n-doped or p-doped,
wherein the additional layer is stacked on, an upper face of the base layer of the thermoelectric sensor.

8. The electronic component of claim 5 , wherein the second thermoelectric member is at least partly housed in a groove provided in the base layer of the thermoelectric sensor and/or, if present, in an additional layer of the thermoelectric sensor.

9. The electronic component of claim 5 , wherein the thermoelectric sensor comprises an electrical insulation coating comprising an electrically insulating material, disposed between the first thermoelectric member and the second thermoelectric member.

10. The electronic component of claim 5 , wherein the first and second thermoelectric members are
in contact in an electrical connection zone ,or
are spaced apart from each other and electrically connected by an electrically conductive bridge.

11. An energy converter, a control unit of a motor, or a microwave power amplifier, comprising:
the electronic component of claim 1.

12. A method for manufacturing an electronic component , comprising a power transistor and a thermoelectric sensor having first and second thermoelectric members, the method comprising :
(a) depositing a first material onto a substrate to form a base layer of the power transistor and a base layer of the thermoelectric sensor, the first material comprising gallium nitride, aluminum gallium nitride, gallium arsenide, gallium indium, gallium indium nitride, aluminum nitride, aluminum indium nitride, or a mixture thereof;
(b) n-type or p-type doping of at least one portion of the base layer of the thermoelectric sensor, or
depositing a second material in contact with the base layer of the thermoelectric sensor in order to form an additional layer of the thermoelectric sensor, followed by n-type or p-type doping of at least one portion, of the additional layer of the thermoelectric sensor,
the second material being different from the first material and comprising gallium nitride, aluminum gallium nitride, gallium arsenide, gallium indium, gallium indium nitride, aluminum nitride, aluminum indium nitride, or a mixture thereof;
(c) forming at least one groove fully passing through the doped portion of the base layer of the thermoelectric sensor or fully passing through the doped portion of the additional layer of the thermoelectric sensor,
with the doped portion of the base layer of the thermoelectric sensor or the additional layer of the thermoelectric sensor contiguous with the groove and extending along the groove defining the first thermoelectric member;
(d) forming at least one electrical insulation coating covering all or part of the one or more faces of the groove;
(e) forming at least one insertion layer at least partly in contact with the electrical insulation coating, and optionally p-type or n-type doping, respectively, the insertion layer, in order to form the second thermoelectric member.

13. The method of claim 12, wherein the doping (b) comprises n-type or p-type doping of at least one portion of the base layer of the thermoelectric sensor, and
wherein the forming (c) comprises forming at least one groove fully passing through the doped portion of the base layer of the thermoelectric sensor,
wherein the doped portion of the base layer of the thermoelectric sensor extends along the groove defining the first thermoelectric member.

14. The method of claim 12, wherein the doping (b) comprises depositing the second material in contact with the base layer of the thermoelectric sensor to form the additional layer of the thermoelectric sensor, followed by the n-type or p-type doping of the at least one portion of the additional layer of the thermoelectric sensor,
wherein the second material differs from the first material and comprises gallium nitride, aluminum gallium nitride, gallium arsenide, gallium indium, gallium indium nitride, aluminum nitride, aluminum indium nitride, or a mixture thereof, and
wherein the forming (c) comprises forming at least one groove fully passing through the doped portion of the additional layer of the thermoelectric sensor,
wherein the doped portion of the additional layer of the thermoelectric sensor is contiguous with the groove and extending along the groove defining the first thermoelectric member.

15. The method of claim 14, comprising, in the doping (b), in conjunction with forming the additional layer of the thermoelectric sensor, depositing the second material onto the base layer of the transistor in order to form an additional layer of the transistor.

16. The method as claimed of claim 12 , further comprising:
depositing a third material in the groove,
wherein the third material is a thermoelectric metal, or a semiconductor material comprising gallium nitride, aluminum gallium nitride, gallium arsenide, gallium indium, gallium indium nitride, aluminum nitride, aluminum indium nitride, or a mixture thereof.

17. The method of claim 12, wherein the forming (d) is conducted so that the electrical insulation coating fully covers the one or more faces of the groove, and
wherein the method further comprises forming an electrical connector electrically connecting the first and second thermoelectric members, in order to form a thermoelectric couple.

18. The method of claim 12 , comprising:
forming a plurality of grooves in the forming (c), with two adjacent grooves being separated by a first adjacent thermoelectric member;
forming a plurality of electrical insulation coatings each at least partially covering the one or more faces of one of the corresponding grooves; and
forming and, optionally, doping, a plurality of insertion layers, each contained in one of the corresponding grooves, and
wherein the optionally doped insertion layers define, with adjacent zones of the doped portion of the base layer of the thermoelectric sensor or of the doped portion of the additional layer of the electrical sensor, a plurality of thermoelectric couples .

19. The electronic component of claim 5, wherein the transistor material is at least one selected from the group consisting of gallium nitride, aluminum gallium nitride, gallium arsenide, gallium indium, gallium indium nitride, aluminum nitride, and aluminum indium nitride.
